(19) United States
(12) Patent Application Publication
(10) Pub. No.: US 2024/0030888 A1
(43) Pub. Date: Jan. 25, 2024

(54) SUBSTRATE FOR SURFACE ACOUSTIC WAVE DEVICE AND SURFACE ACOUSTIC WAVE DEVICE COMPRISING THE SAME

(71) Applicant: POSTECH RESEARCH AND BUSINESS DEVELOPMENT FOUNDATION, Pohang-si (KR)

(72) Inventors: Byoung Don KONG, Pohang-si (KR); Seok Hyun YOON, Pohang-si (KR); Hyeon Su CHO, Pohang-si (KR); Seung Ho LEE, Pohang-si (KR); Gyeong Min SEO, Pohang-si (KR); Chang Ki BAEK, Pohang-si (KR)

(73) Assignee: POSTECH RESEARCH AND BUSINESS DEVELOPMENT FOUNDATION, Pohang-si (KR)

(21) Appl. No.: 18/254,131

(22) PCT Filed: Nov. 17, 2021
(86) PCT No.: PCT/KR2021/016917

§ 371 Date: May 23, 2023

(30) Foreign Application Priority Data
Nov. 23, 2020 (KR) 10-2020-0157468
Sep. 3, 2021 (KR) 10-2021-0117313

(51) Int. Cl. H03H 9/02; H03H 9/64; H03H 9/72

(52) U.S. Cl. CPC H03H 9/02574; H03H 9/64; H03H 9/72

(57) ABSTRACT

There is provided a substrate for a surface acoustic wave device, comprising a 2-dimensional (2D) crystalline hexagonal boron nitride layer, wherein a surface acoustic wave of the surface acoustic wave device is transmitted through the 2D crystalline hexagonal boron nitride layer.

### TECHNICAL FIELD

The present disclosure relates to a substrate for a surface acoustic wave device and a surface acoustic wave device comprising the same, and more particularly, to a substrate for a surface acoustic wave device that can operate at high frequency by defining for the surface acoustic wave device, as the substrate, crystalline hexagonal boron nitride having higher phase velocity than piezoelectric materials that have been used for substrates of surface acoustic wave devices, and a surface acoustic wave device comprising the same.

### BACKGROUND ART

Surface Acoustic Wave (SAW) devices have a wide range of industrial applications including Intermediate Frequency (IF) filters used in TVs, Radio Frequency (RF) filters used for long distance communication of mobile phones and different types of sensors. The surface acoustic wave devices are essential for many electronic devices and wireless communication systems. Recently, in keeping up with trends toward multifunction and small size, there is a growing demand for high performance surface acoustic wave devices, and in particular, as the communication frequency band increases, surface acoustic wave devices operating in the high frequency band are required. Additionally, a standing surface acoustic wave may form a potential barrier of a predetermined shape on the surface of a nearby solid, and surface acoustic wave devices are used in a wide range of applications including spin information processing and quantum computers for information processing using the spin of charge confined in the potential barrier.

In general, the surface acoustic wave device includes Interdigital Transducer (IDT) metal electrodes and a piezoelectric material as a medium in which an acoustic wave is generated and propagates. The piezoelectric effect serves to convert an electrical signal to a mechanical signal and a mechanical signal to an electrical signal. Specifically, when an electrical signal is applied to the interdigital transducer electrodes, mechanical stress is induced by geometric deformation of the piezoelectric material film that generates a surface acoustic wave, and is converted to a traveling surface acoustic wave and propagates along the surface of the piezoelectric material. Information transmitted by the surface acoustic wave on the substrate surface is converted from the mechanical acoustic wave to the electrical signal through the other interdigital transducer electrodes in a propagation path. The center frequency f₀ at which the surface acoustic wave device operates is represented by the following equation.

f₀=v₀/λ

Accordingly, the operating frequency is determined by the velocity v₀ of the acoustic wave and the wavelength λ of the interdigital transducer electrodes. Recently, as the amount of information transmitted dramatically increases, the high frequency operation of surface acoustic wave devices is required, and many studies are being made to develop devices that operate at higher frequency of a few tens of GHz. To increase the center frequency, there are methods of increasing the velocity of the acoustic wave or decreasing the electrode interval which is the cycle of the interdigital transducer electrodes corresponding to the wavelength of the acoustic wave. However, it is difficult to reduce the electrode size and the electrode interval below a few tens of nm due to the limitations of the process for forming the interdigital transducer metal, and there are many problems with fabrication reliability encountered in mass production.

By this reason, in order to reach a few tens of GHz band using the existing materials, attempts are recently being made to use harmonics of the center frequency or a special waveform (Sezawa mode) generated at the interface with a material having high velocity of an acoustic wave such as diamond.

However, compared to the fundamental frequency of harmonics or special waveform, the coupling efficiency decreases and signal attenuation to the input signal and low Signal-to-Noise Ratio (SNR) are unavoidable. Accordingly, the method of increasing the velocity of the acoustic wave in the medium which is the most basic element that determines the operating frequency is the most fundamental solution to increase the center frequency.

The velocity of the acoustic wave is primarily a unique characteristic of the piezoelectric material, and examples of the main piezoelectric material being used or studied include LiNbO₃(LN), LiTaO₃(LT), PZT, ZnO and AlN. Additionally, in ultrahigh frequency applications, studies are made to apply a ZnO or AlN thin film on a diamond or sapphire substrate having high velocity of the surface wave.

However, these materials have the center frequency of the fundamental wave up to 15 GHz due to the limited phase velocity, and thus cannot be used in 5G band communication as high as 30 GHz. When the above-described harmonics or interfacial waveforms are used, the center frequency increases but efficiency decreases.

Accordingly, in the era of IoT requiring small size, high performance and processing of large amount of information in high frequency bands, for faster processing of larger amount of information, it is necessary to improve the performance in order to overcome the limitations of the existing surface acoustic wave devices.

Further, the inventors studied a surface acoustic wave device that can operate at high frequency by defining, as a substrate of the surface acoustic wave device, crystalline hexagonal boron nitride having higher phase velocity than piezoelectric materials that have been used for substrates of surface acoustic wave devices, but the direct use of piezoelectric materials has limitations in harmonics generation.

### RELATED LITERATURES

1. E. Dogheche, D. Remiens. “High-frequency surface acoustic wave devices based on LiNbO₃/diamond multilayered structure”, Applied Physcis Letters 87, 213503 (2005)
2. Natalya F. Naumenko. “High-velocity non-attenuated acoustic waves in LiTaO₃/quartz layered substrates for high frequency resonators”, Ultrasonics 95 (2019) 1-5
3. S. Büyükköse “Ultrahigh-frequency surface acoustic wave transducers on ZnO/SiO₂/Si using nanoimprint lithography”, Nanotechnology 23 (2012) 315303
4. Y. Takagaki. “Enhanced performance of 17.7 GHz SAW devices based on AlN/diamond/Si layered structure with embedded nanotransducer”, Applied Physics Letters 111, 253502 (2017)
5. Lei Wang et al., “Enhanced performance of 17.7 GHz SAW devices based on AlN/diamond/Si layered structure with embedded nanotransducer”, Appl, Phys. Lett. 111, 253502 (2017)
6. Jiangpo Zheng et al., “30 GHz surface acoustic wave transducers with extremely high mass sensitivity”, Appl. Phys. Lett. 116, 123502 (2020)
7. <Surface Acoustic Wave(SAW) Devices Based on Cubic Boron Nitride/Diamond Composite Structures>, U.S. Pat. No. 7,579,759 B2
8. <Stacked Piezoelectric Surface Acoustic Wave Device with A Boron Nitride Layer in The Stack>, U.S. Pat. No. 5,463,901
9. Chinese Patent Publication No. 201210061500

### DISCLOSURE

### Technical Problem

Accordingly, the disclosure is directed to providing an improved substrate for a surface acoustic wave device that operates at high frequency and a device comprising the same.

### Technical Solution

To solve the above-described problem, the present disclosure provides a substrate for a surface acoustic wave device, comprising a 2-dimensional (2D) crystalline hexagonal boron nitride layer, wherein a surface acoustic wave of the surface acoustic wave device is transmitted through the 2D crystalline hexagonal boron nitride layer.

The present disclosure further provides a surface acoustic wave device, comprising a substrate; an input transducer stacked on the substrate and configured to induce a surface acoustic wave; and an output transducer stacked on the substrate and configured to detect the induced surface acoustic wave on the substrate, wherein the substrate is defined in any one of claims 1 to 5.

### Advantageous Effects

According to the present disclosure, it is possible to realize the surface acoustic wave device that can operate at high frequency by defining, as a substrate of the surface acoustic wave device, crystalline hexagonal boron nitride having higher phase velocity than piezoelectric materials that have been used for substrates of surface acoustic wave devices. Currently, commercially available surface acoustic wave devices using the existing materials operate at 3 GHz frequency, and the present disclosure presents the center frequency of a fundamental wave above 20 GHz, and when using harmonics (high-order modes), can operate in the V-band (40 to 75 GHz).

### DESCRIPTION OF DRAWINGS

FIG. 1 is a cross-sectional view showing a 2-dimensional (2D) crystalline hexagonal boron nitride based surface acoustic wave device according to a first embodiment of the present disclosure.

FIG. 2 is a conceptual diagram illustrating the operation of a 2D crystalline hexagonal boron nitride based surface acoustic wave device according to a first embodiment of the present disclosure.

FIG. 3 is a conceptual diagram illustrating a high frequency filter using a 2D crystalline hexagonal boron nitride based surface acoustic wave device according to a second embodiment of the present disclosure.

FIG. 4 is a diagram illustrating a device structure of a third embodiment with a piezoelectric material layer having slow wave velocity stacked on a crystalline hexagonal boron nitride layer to generate harmonics according to another embodiment of the present disclosure.

FIG. 5 is a conceptual diagram illustrating the operation of a 2D crystalline hexagonal boron nitride based surface acoustic wave device according to a third embodiment of the present disclosure.

FIG. 6 is a top view of the components of a high frequency filter interdigital transducer according to a second embodiment of the present disclosure.

FIG. 7 shows a crystal model of crystalline hexagonal boron nitride in which a surface acoustic wave of a high frequency filter according to a second embodiment of the present disclosure is generated and propagates.

FIG. 8 shows simulation results per one wavelength of a periodic interdigital transducer of a high frequency filter according to a second embodiment of the present disclosure, showing an electric displacement field in the fundamental resonant frequency of a medium generated by a piezoelectric phenomenon in response to an applied voltage.

FIG. 9 shows simulation results of a pair of interdigital transducers of a high frequency filter for inducing a surface acoustic wave and detecting the surface acoustic wave at an input terminal and an output terminal with the structure of FIG. 8 according to a second embodiment of the present disclosure, showing an electric displacement field in the fundamental resonant frequency of a medium generated by a piezoelectric phenomenon in response to an applied voltage.

FIG. 10 shows frequency response characteristics of the high frequency filter of FIG. 9 according to a second embodiment of the present disclosure.

FIG. 11 shows S-parameter analysis results of the high frequency filter of FIG. 9 according to a second embodiment of the present disclosure.

FIG. 12 shows simulation results per one wavelength of a periodic interdigital transducer of a high frequency filter according to a third embodiment of the present disclosure, showing an electric displacement field distribution in the fundamental resonant frequency when LiNbO₃ is used as a piezoelectric material.

FIG. 13 shows simulation results of a pair of interdigital transducers of a high frequency filter for inducing a surface acoustic wave and detecting the surface acoustic wave at an input terminal and an output terminal according to a third embodiment of the present disclosure, showing an electric displacement field distribution in the fundamental resonant frequency.

FIG. 14 shows simulation results per one wavelength of a periodic interdigital transducer of a high frequency filter according to a third embodiment of the present disclosure, showing an electric displacement field distribution in the first harmonic when LiNbO₃ is used as a piezoelectric material.

FIG. 15 shows simulation results of a pair of interdigital transducers of a high frequency filter for inducing a surface acoustic wave and detecting the surface acoustic wave at an input terminal and an output terminal with the structure of FIG. 14 according to a third embodiment of the present disclosure, showing an electric displacement field distribution in the first harmonic.

FIG. 16 shows frequency response characteristics when LiNbO₃ and LiTaO₃ are used in a piezoelectric material layer, in the high frequency filter of FIGS. 13 and 15 according to a third embodiment of the present disclosure.

FIG. 17 shows S-parameter analysis results when LiNbO₃ and LiTaO₃ are used in a piezoelectric material layer, in the high frequency filter of FIGS. 13 and 15 according to a third embodiment of the present disclosure.

FIG. 18 is a table showing a comparison of highest natural frequency and electromechanical coupling coefficient for each of 2D crystalline hexagonal boron nitride according to a third embodiment of the present disclosure and existing surface acoustic wave device materials.

FIG. 19 is a graph showing a phonon dispersion relationship calculated by the universal density functional theory, i.e., a relationship between frequency and energy.

FIG. 20 is a conceptual diagram of a high speed communication device between semiconductor chips using a 2D crystalline hexagonal boron nitride based surface acoustic wave device according to the present disclosure.

FIG. 21 is a conceptual diagram of a quantum and spin information processing device using a 2D crystalline hexagonal boron nitride based surface acoustic wave device according to the present disclosure.

FIG. 22 is a conceptual diagram of a 2D quantum and spin information processing device extended from a 1D surface acoustic wave illustrated in FIG. 21 of the present disclosure.

### BEST MODE

Many modifications and changes may be made to the present disclosure, and particular embodiments are shown in the accompanying drawings by way of illustration and will be described in detail below. However, the present disclosure is not intended to be limited to the disclosed particular embodiments, and rather, the present disclosure includes all modifications, equivalents and substituents that fall within the spirit of the present disclosure defined by the appended claims. In describing each drawing, similar reference signs are used to similar elements.

When an element such as a layer, a region or a substrate is referred to as being present “on” another element, it will be understood that it may be directly on the other element or intervening elements may be present.

Unless otherwise defined, all terms used herein including technical and scientific terms have the same meaning as commonly understood by one of ordinary skill in the art. The commonly understood terms should be interpreted as having a meaning that is consistent with their meaning in the context of the relevant art, and will not be interpreted in an idealized or overly formal sense unless expressly so defined herein.

In the present disclosure, when a layer is referred to as being present “on” another layer or a substrate, it may be directly formed on the other layer or the substrate, or a third layer may be present between them. Additionally, in the present disclosure, a directional representation such as up, above and an upper surface may be understood as the meaning of down, below, a lower surface according to the reference. That is, the representation of spatial direction should be understood as a relative direction and should not be interpreted as being limited to an absolute direction.

The exemplary embodiments of the present disclosure will be described in more detail with reference to the accompanying drawings. Hereinafter, the same reference signs are used for the same elements in the drawings, and redundant descriptions of the same elements are omitted.

The present disclosure presents a surface acoustic wave substrate of 2-dimensional (2D) crystalline hexagonal boron nitride and a new high frequency surface acoustic wave device comprising the same. Further, since crystalline hexagonal boron nitride is a very solid material, the fundamental resonant frequency may be high due to high sound velocity, but the piezoelectric effect is weak, and an electromechanical coupling coefficient K² value indicating how much input signal is converted to an electrical signal by the piezoelectric effect is relatively low. To solve this problem, a piezoelectric material layer is stacked on the crystalline hexagonal boron nitride layer. Accordingly, it is possible to provide very fast harmonics characteristics and improved electrical signal detection characteristics by generating harmonics (high-order modes) at the interface between the material layer (the crystalline hexagonal boron nitride layer) having fast wave velocity and the material layer (the piezoelectric material layer) having slow wave velocity.

### First Embodiment

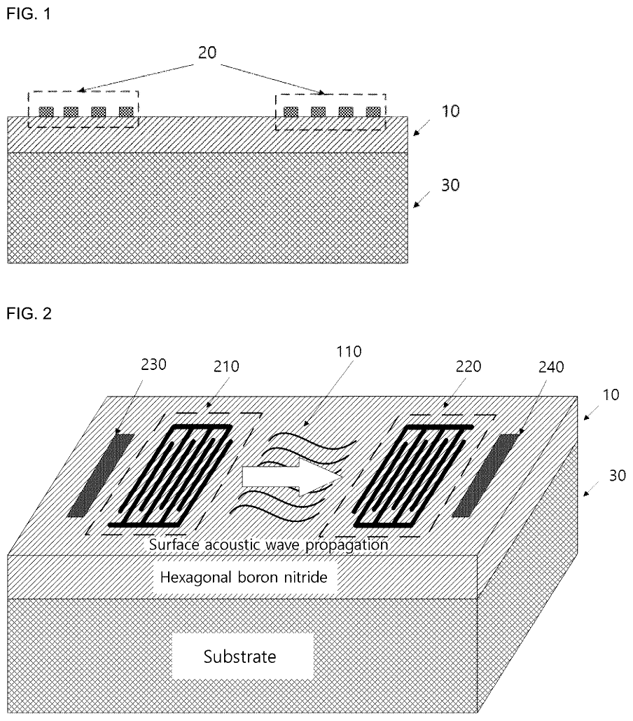

FIG. 1 is a cross-sectional view showing a 2D crystalline hexagonal boron nitride based surface acoustic wave device according to a first embodiment of the present disclosure.

Referring to FIG. 1, a substrate according to an embodiment of the present disclosure includes a support substrate 30 and an exposed 2D crystalline hexagonal boron nitride layer 10 stacked on the support substrate 30.

That is, in the present disclosure, the ‘substrate’ includes the support substrate 30, and the boron nitride layer 10 on the support substrate to cause regular contraction and expansion to induce a surface acoustic wave or generate a spatially and temporally regular potential difference caused by the surface acoustic wave.

The present disclosure further provides a surface acoustic wave device including the substrate.

The surface acoustic wave device according to an embodiment of the present disclosure includes the mono- or multi-layered 2D crystalline hexagonal boron nitride layer 10; interdigital type input and output transducer electrodes 20 to apply the spatially and temporally regular potential difference to the boron nitride layer 10 to cause the regular contraction and expansion to the 2D crystalline hexagonal boron nitride layer 10 to induce the surface acoustic wave or read the spatially and temporally regular potential difference caused by the surface acoustic wave traveling in the 2D crystalline hexagonal boron nitride layer 10; and the support substrate 30 to support the boron nitride layer 10 and the interdigital transducer electrodes 20.

In the present disclosure, the support substrate 30 does not affect the insulating properties of the 2D crystalline hexagonal boron nitride layer 10 stacked thereon, and all or part of the stacked 2D crystalline hexagonal boron nitride layer is exposed upward or downward of the support substrate to allow the surface acoustic wave to travel in the 2D crystalline hexagonal boron nitride layer 10 supported by the support substrate 30.

Additionally, the input transducer or the output transducer may include Al, Au, Pt, Ni, Cr, Cd, Ti, W, Pd, Ag, Cu, Ru, Rh, Ta, Mo, Nb, doped NiSi, TaSiN, ErSi_{1.7}, PtSi, WSi₂, NbN conductive ceramics, doped Si, Ge, III-V compound semiconductors and a combination thereof.

FIG. 2 is a conceptual diagram illustrating the operation of the 2D crystalline hexagonal boron nitride based surface acoustic wave device according to the first embodiment of the present disclosure. The 2D crystalline hexagonal boron nitride based surface acoustic wave device may include, on the 2D crystalline hexagonal boron nitride film 10, interdigital transducer electrodes 210 for inducing the surface acoustic wave and interdigital transducer electrodes 210 for detecting the surface acoustic wave traveling across a channel region 110 on the 2D crystalline hexagonal boron nitride film in which the induced surface acoustic wave travels, and absorptive or reflective layers 230, 240 for attenuation of the surface acoustic wave to prevent signal interference by propagation, reflection, or scattering of an unintended surface acoustic wave. Additionally, these components may be placed on the support substrate 30 of various types that does not interfere with the physical properties necessary for the operation of the surface acoustic wave device.

Further, the present disclosure may control the propagation characteristics (for example, attenuation) of the surface acoustic wave according to the isotope ratio of nitrogen and boron. In the case of boron, natural occurring stable isotopes exist at a high ratio (¹⁰B:¹¹B=20:80), and in the case of nitrogen, there are stable isotopes having a low ratio (¹⁴N:¹⁵N=99.6:0.4) but a long half-life. The isotope is equal in electrical coupling, but has a mass difference due to a difference in the number of neutrons. The same type of atoms that form crystals have different mass and their increasing randomness causes fast attenuation by scattering of the surface acoustic wave. Accordingly, the boron nitride layer including boron or nitrogen having the same atomic weight through isotope separation of boron and nitrogen may have long propagation distance characteristics through the decreased attenuation of the surface acoustic wave. Additionally, in the case of hexagonal boron nitride consisting of ¹⁰B and ¹⁴N having low mass, the mass decreases for the same coupling strength, thereby improving the phase velocity. When scattering by a so-called mass defect or a mass difference between isotopes is at the maximum, the attenuation of the surface acoustic wave may be also at the maximum, and this occurs when the isotope ratio is adjusted to a ratio close to 50%, and may be used as an absorption layer to prevent the surface acoustic wave from traveling. Accordingly, it signifies that the characteristics of the acoustic wave may be controlled by adjusting the isotope ratio according to desired device characteristics.

### Second Embodiment

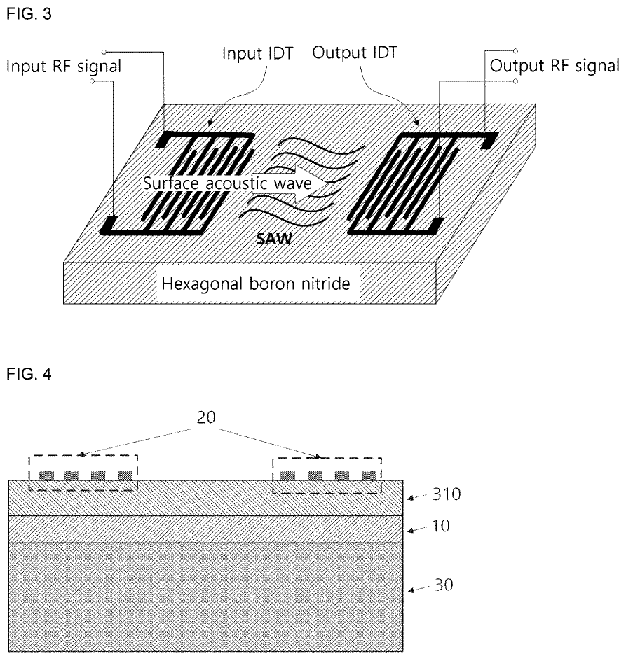

FIG. 3 is a conceptual diagram illustrating a high frequency filter using a 2D crystalline hexagonal boron nitride based surface acoustic wave device according to a second embodiment of the present disclosure. When a RF signal is applied to the interdigital transducer electrodes that convert an input signal to a surface acoustic wave, the RF signal is converted to a surface acoustic wave to output only a signal corresponding to the natural frequency generated by the designed interdigital transducer and the 2D crystalline hexagonal boron nitride.

When the traveling surface acoustic wave reaches the output interdigital transducer electrodes spaced a predetermined distance apart, the traveling surface acoustic wave is converted to an electrical signal and detected as an output RF signal. Even though the RF signal of wide bandwidth is applied to the input terminal through the above-described process, only the signal corresponding to the natural frequency generated by the interdigital transducer and the 2D crystalline hexagonal boron nitride may be separated and converted to the output signal, and thus this acts as a band filter for the input RF signal.

### Third Embodiment

FIG. 4 is a cross-sectional showing a surface acoustic wave device of a third embodiment with a piezoelectric material layer 310 having slow wave velocity stacked on the hexagonal boron nitride layer 10 to generate harmonics according to another embodiment of the present disclosure.

In FIG. 4, the substrate 30—the hexagonal boron nitride 10—the interdigital transducer 20 are stacked in the same way as FIG. 1, and the piezoelectric material 310 is additionally stacked on the hexagonal boron nitride layer 10.

Additionally, the piezoelectric material 310 may include α-AlPO₄, Quartz, LiNbO₃, LiTaO₃, SrₓBa_{y}Nb₂O₈, Pb₅—Ge₃O₁₁, Tb₂(MoO₄)₃, Li₂B₄O₇, Bi₁₂SiO₂₀, Bi₁₂GeO₂₀, PZT, PT, PZT-Complex Perovskite, BaTiO₃, ZnO, Cds, AlN. Subsequently, it operates in the same way as the second embodiment.

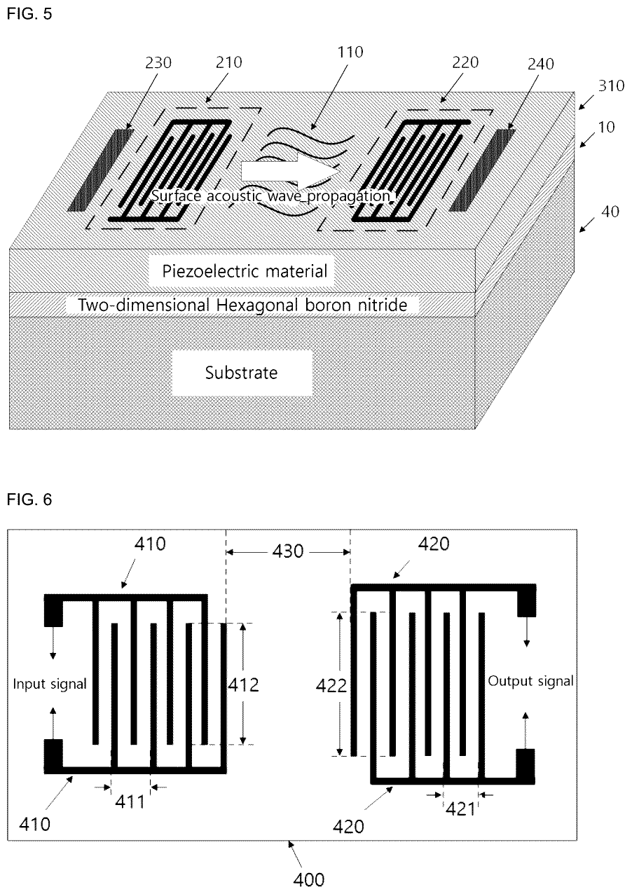

FIG. 5 is a conceptual diagram illustrating the operation of the 2D crystalline hexagonal boron nitride based surface acoustic wave device according to the third embodiment of the present disclosure.

FIG. 6 is a top view of the components of the high frequency filter interdigital transducer according to the second and third embodiments of the present disclosure. The pair of interdigital transducers includes the interdigital transducer 410 for inducing the surface acoustic wave through signal input and the interdigital transducer 420 for output through detection of the surface acoustic wave, and each interdigital transducer includes electrodes arranged at predetermined intervals 411, 421 that match the cycle of the natural frequency. That is, the dimensions such as electrode lengths 412, 422 of the pair of interdigital transducers and a distance 430 between the interdigital transducers may be differently designed according to the optimal condition of signal transmission and detection.

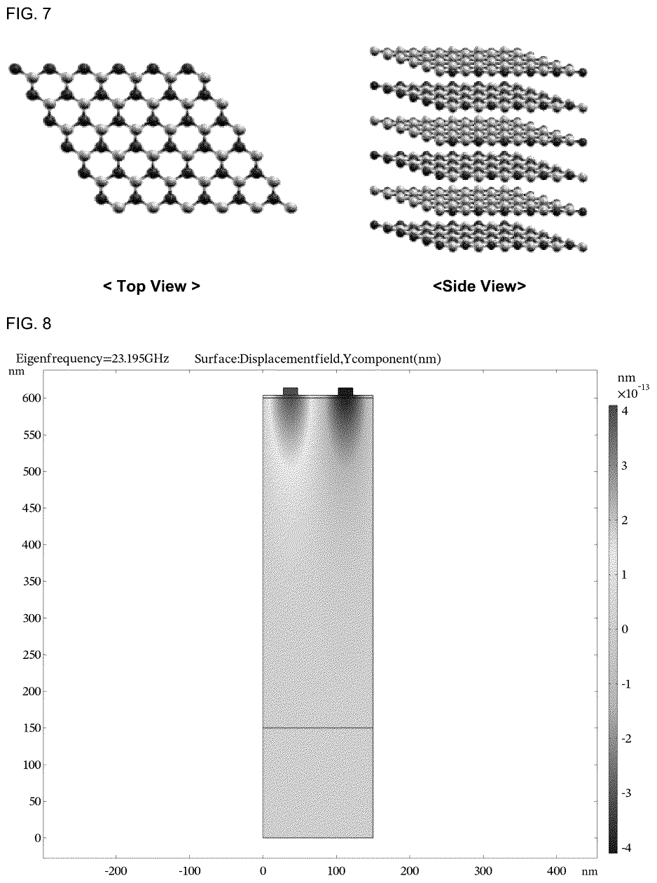

FIG. 7 shows a crystal model of the crystalline hexagonal boron nitride in which the surface acoustic wave of the high frequency filter according to the second embodiment of the present disclosure is generated and propagates.

FIG. 8 shows simulation results per one wavelength of the periodic interdigital transducer of the high frequency filter according to the second embodiment of the present disclosure, showing an electric displacement field in the fundamental resonant frequency of the medium generated by a piezoelectric phenomenon in response to an applied voltage. The 4 nm-thick crystalline hexagonal boron nitride is placed on the insulating substrate of SiO₂ and two electrodes of 10 nm in height and 20 nm in width are arranged at the distance of 55 nm, and the structure having the wavelength of 150 nm forms one cycle. In the structure of FIG. 8, the natural frequency of the fundamental wave amounts to 23.195 GHz.

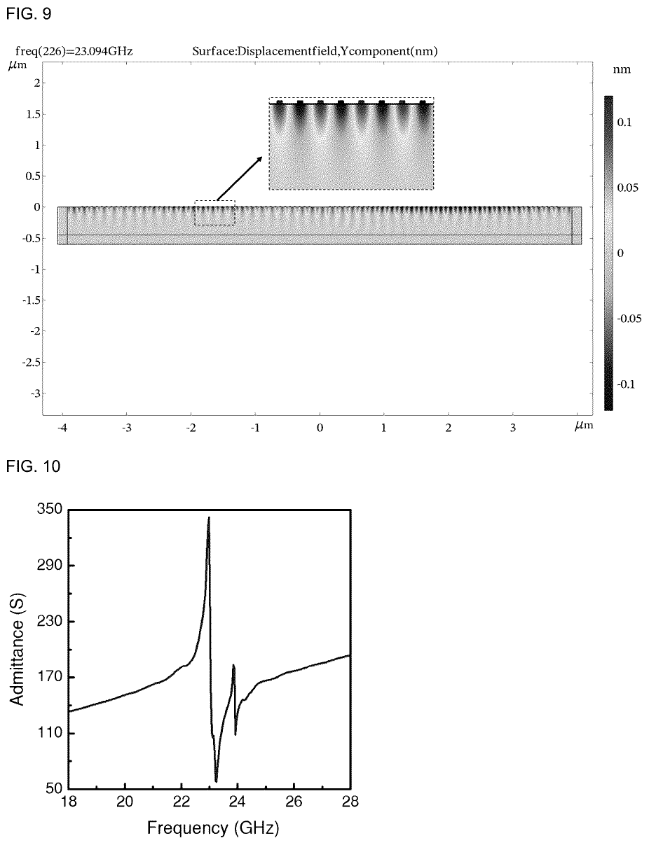

FIG. 9 shows simulation results of the pair of interdigital transducers of the high frequency filter for inducing the surface acoustic wave and detecting the surface acoustic wave signal at the input terminal and the output terminal with the structure of FIG. 8 according to the second embodiment of the present disclosure, showing the electric displacement field at the fundamental resonant frequency of the medium generated by the piezoelectric phenomenon in response to the applied voltage. It can be seen that the applied voltage travels in the form of a shrinking and expanding acoustic wave that matches the wavelength by the piezoelectric phenomenon from the interdigital transducer for inducing the surface acoustic wave and is transmitted to the interdigital transducer for detection.

Each of the interdigital transducers at the two terminals includes 50 metal electrodes, and the left one is for inducing the surface acoustic wave, and the right one is for detecting the surface acoustic wave.

Compared with the simulation of FIG. 8 in which the cycle repeats indefinitely, when the number of electrodes becomes definite as shown in FIG. 9, the natural frequency of the system changes by the interference with the boundaries and the adjacent interdigital transducer. The natural frequency of the simulation structure of FIG. 9 amounts to 23.094 GHz, which is slightly lower than 23.195 GHz but shows higher performance than other material. Additionally, the frequency may be further improved by adjusting the electrode size, distance and cycle.

FIG. 10 shows frequency response characteristics of the high frequency filter of FIG. 9 according to the second embodiment of the present disclosure. It can be seen that the natural frequency of the fundamental wave appears near 23 GHz.

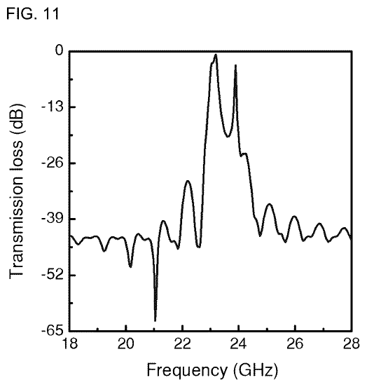

FIG. 11 shows S-parameter analysis results of the high frequency filter of FIG. 9 according to the second embodiment of the present disclosure. It can be seen that the lowest propagation loss appears near 23 GHz natural frequency of the fundamental wave. Accordingly, it can be seen that only the signal of frequency band near the natural frequency is filtered and thus it acts as a band filter.

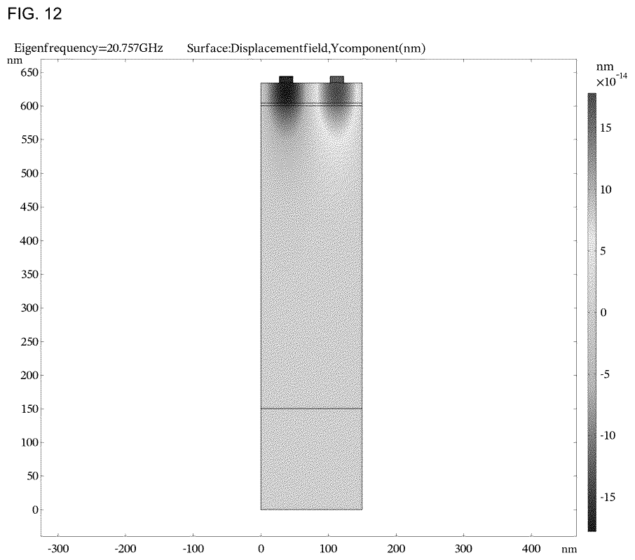

FIG. 12 shows simulation results per one wavelength of the periodic interdigital transducer of the high frequency filter according to the third embodiment of the present disclosure, showing an electric displacement field distribution in the fundamental resonant frequency when LiNbO₃ is used as the piezoelectric material. The 4 nm-thick crystalline hexagonal boron nitride is placed on the insulating substrate of SiO₂, and two electrodes of 10 nm in height and 20 nm in width are arranged at the distance of 55 nm, and the structure having the wavelength of 150 nm forms one cycle. In the structure of FIG. 12, the natural frequency of the fundamental wave amounts to 20.757 GHz.

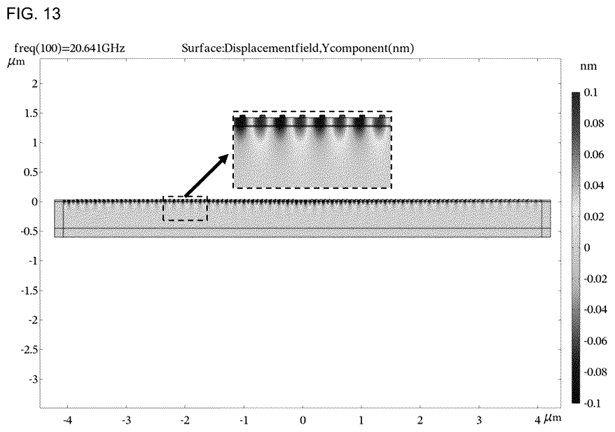

FIG. 13 shows simulation results of the pair of interdigital transducers of the high frequency filter for inducing the surface acoustic wave and detecting the surface acoustic wave according to the third embodiment of the present disclosure at the input terminal and the output terminal, showing the electric displacement field distribution in the fundamental resonant frequency.

Each of the interdigital transducers at the two terminals includes 50 metal electrodes, and the left one is for inducing the surface acoustic wave and the right one is for detecting the surface acoustic wave.

Compared with the simulation of FIG. 12 in which the cycle repeats indefinitely, when the number of electrodes becomes definite as shown in FIG. 13, the natural frequency of the system changes by the interference with the boundaries and the adjacent interdigital transducer. The natural frequency of the simulation structure of FIG. 13 amounts to 20.641 GHz, which is slightly lower than 20.757 GHz but shows higher performance than other material. Additionally, the frequency may be further improved by adjusting the electrode size, distance and cycle, and high-order modes may operate at the frequency corresponding to a few multiples of the fundamental wave.

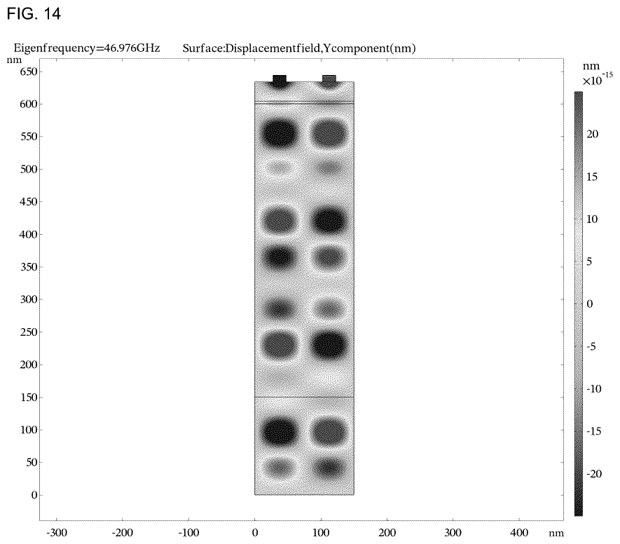

FIG. 14 shows simulation results per one wavelength of the periodic interdigital transducer of the high frequency filter according to the third embodiment of the present disclosure, showing the electric displacement field distribution in the first harmonic when LiNbO₃ is used as the piezoelectric material.

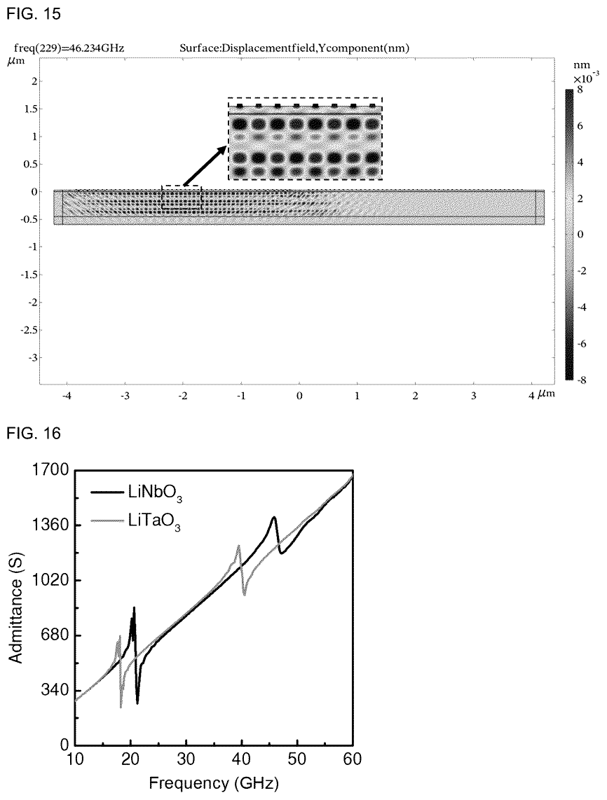

FIG. 15 shows simulation result of the pair of interdigital transducers of the high frequency filter for inducing the surface acoustic wave and detecting the surface acoustic wave at the input terminal and the output terminal with the structure of FIG. 14 according to the third embodiment of the present disclosure, showing the electric displacement field distribution in the first harmonic.

Each of the interdigital transducers at the two terminals includes 50 metal electrodes, and the left one is for inducing the surface acoustic wave, and the right one is for detecting the surface acoustic wave.

Compared with the simulation of FIG. 14 in which the cycle repeats indefinitely, when the number of electrodes becomes definite as shown in FIG. 15, the natural frequency of the system changes by the interference with the boundaries and the adjacent interdigital transducer. The natural frequency of the simulation structure of FIG. 15 amounts to 46.234 GHz, which is slightly lower than 46.976 GHz but shows higher performance than other material. Additionally, the frequency may be further improved by adjusting the electrode size, distance and cycle, and high-order modes may operate at the frequency corresponding to a few multiple of the first harmonic.

FIG. 16 shows frequency response characteristics when LiNbO₃ and LiTaO₃ are used in the piezoelectric material layer, in the high frequency filter of FIGS. 13 and 15 according to the third embodiment of the present disclosure.

It can be seen that the lowest propagation loss appears near 23 GHz natural frequency of the fundamental wave. Accordingly, it can be seen that only the signal in the frequency band near the natural frequency is filtered and thus it acts as a band filter.

### First Comparative Example

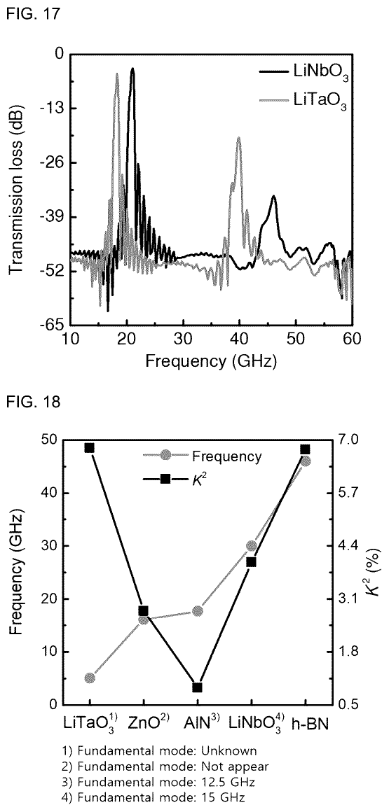

FIG. 16 shows operating frequency analysis results of the third embodiment with two types of piezoelectric material layers stacked on the 2D crystalline hexagonal boron nitride layer, and FIG. 17 shows S-parameter analysis results.

Referring to FIG. 16, it can be seen that the two types of piezoelectric materials have the fundamental resonant frequency near 20 GHz, and the first harmonic appears at or above 40 GHz.

Additionally, referring to FIG. 17, peaks appear in the fundamental resonant frequency and the first harmonic, and LiNbO₃ has the propagation loss of 3.4 and 34 dB in the fundamental resonant frequency and the first harmonic, respectively, and LiTaO₃ has the propagation loss of 4.7 and 20 dB in the fundamental resonant frequency and the first harmonic, respectively. Additionally, the calculated electromechanical coupling coefficient of LiNbO₃ having higher operating frequency is 2.62% and 6.76% in the fundamental resonant frequency and the first harmonic, respectively, and this is the result of a few fold improvement compared to the fundamental resonant frequency at the resonant frequency of the first embodiment structure using no piezoelectric material layer having an electromechanical coupling coefficient value of 1% or less.

Accordingly, when the piezoelectric material layer is used together with the 2D crystalline hexagonal boron nitride layer according to the present disclosure, it is possible to realize the substrate for surface acoustic wave having two advantages of high electromechanical coupling coefficient and high surface acoustic wave velocity of hexagonal boron nitride by only a simple stacking process without using a high cost substrate such as diamond.

### Second Comparative Example

FIG. 18 shows a comparison table of the highest natural frequency of each of the 2D crystalline hexagonal boron nitride according to the third embodiment of the present disclosure and the existing surface acoustic wave device materials and their electromechanical coupling coefficient. In the case of the surface acoustic wave device using the 2D crystalline hexagonal boron nitride showing much higher phase velocity than lithium niobate (LiNbO₃), lithium tantalite (LiTaO₃), zinc oxide (ZnO) and aluminum nitride (AlN) widely used in the existing surface acoustic wave devices, it can be seen that the natural frequency of the first harmonic amounts to the V-band (40 to 75 GHz) frequency band. This results from the phase velocity amounting to 19,600 m/s in the in-plane direction due to high elastic modulus and 2D device characteristics of the 2D crystalline hexagonal boron nitride, and the higher the phase velocity, the longer the wavelength at the same natural frequency. Additionally, it can be seen that the electromechanical coupling coefficient is much higher than those of the surface acoustic wave devices that operate at the ultra high frequency.

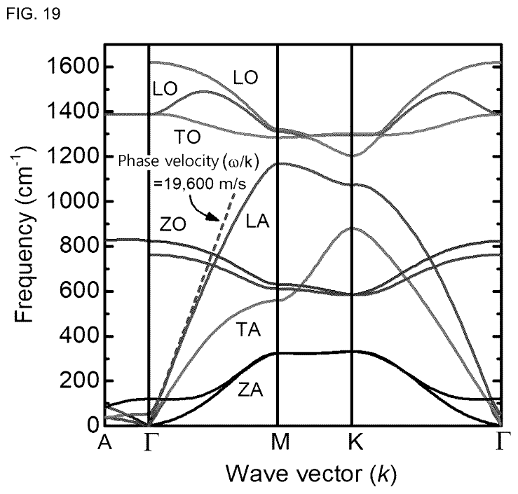

FIG. 19 is a graph showing a phonon dispersion relationship calculated by the universal density functional theory, i.e., a relationship between frequency and energy.

In FIG. 19, the atomic weight of boron and nitrogen for calculation uses values at average ratios of naturally occurring isotopes, and the slope of variation of the longitudinal acoustic wave (LA) is a sound velocity. LO refers to the longitudinal optical wave, and TA and TO refer to the transverse acoustic wave and transverse optical wave in the in-plane direction, respectively. ZA and ZO refer to the transverse acoustic wave and transverse optical wave in the out-of-plane direction, respectively.

Referring to FIG. 19, it can be seen that the phase velocity in the in-plane direction amounts to 19,600 m/s.

Theoretically, the natural frequency may be improved by reducing the cycle of the interdigital transducer in proportion to the wavelength, but due to the fabrication process or crystal defects, the natural frequency cannot increase boundlessly, and since there are technical limitations in mass production of the uniform electrode arrangement having the width of 10 nm or less, the length of a few μm or more and the cycle of 100 nm or less with reproducibility, high phase velocity is very important for the surface acoustic wave device that operates at a few tens of GHz band, and the 2D crystalline hexagonal boron nitride of the present disclosure suggests the best solution.

### Fourth Embodiment

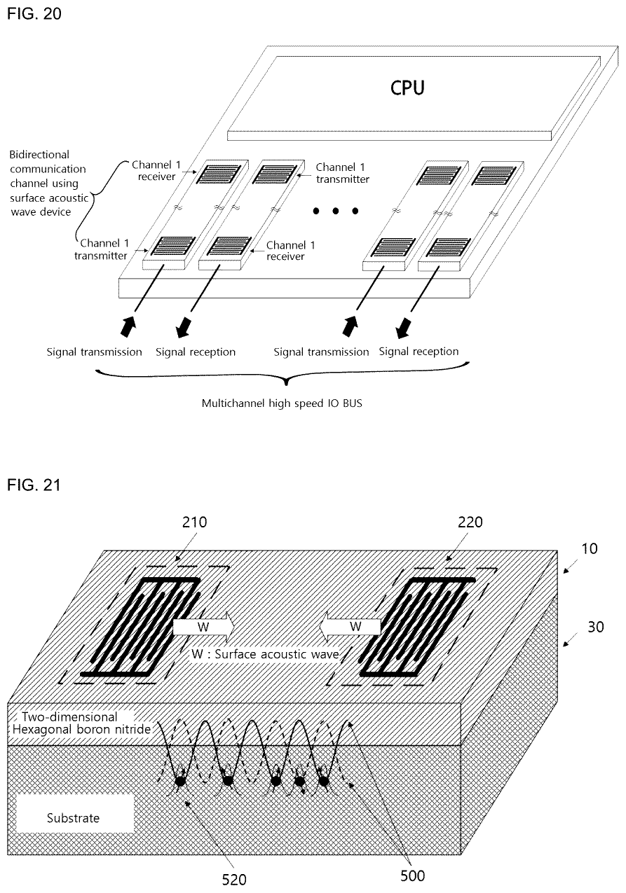

FIG. 20 is a conceptual diagram of a high speed communication device between semiconductor chips using the 2D crystalline hexagonal boron nitride based surface acoustic wave device according to the present disclosure, and is an example of the use of the pair of interdigital transducers for input and output as a unidirectional channel. One interdigital transducer is used for input and output to form a bidirectional channel or two unidirectional channels are combined to form a bidirectional channel. The plurality of channels may form a multichannel high speed input/output bus.

### Fifth Embodiment

FIG. 21 is a conceptual diagram of a quantum and spin information processing device using the 2D crystalline hexagonal boron nitride based surface acoustic wave device according to the present disclosure. When two interdigital transducers are placed facing each other to induce the surface acoustic wave on two sides to form a standing wave of the surface acoustic wave, a potential barrier 500 of the same cycle as the standing wave is formed near the 2D crystalline hexagonal boron nitride surface. The potential barrier 500 excites the potential barrier to an adjacent semiconductor or metalloid material and charge confined to the potential barrier has a unique energy state and spin state.

Accordingly, the quantum and spin information processing device including the surface acoustic wave device according to the present disclosure forms the standing wave by at least two surface acoustic waves and the potential barrier near the 2D crystalline hexagonal boron nitride surface by the standing wave, and confines the charge 520 by excitation of the same potential barrier to the adjacent semiconductor or metalloid material from the potential barrier. Accordingly, the information processing device according to the present disclosure may store and read the unique energy and spin state of the confined charge.

Subsequently, the charge may move by the guided interaction by slowing down the cycle of the standing wave or the standing wave to lower the potential barrier between the confined charges 520, and quantum and spin information processing is possible through this process.

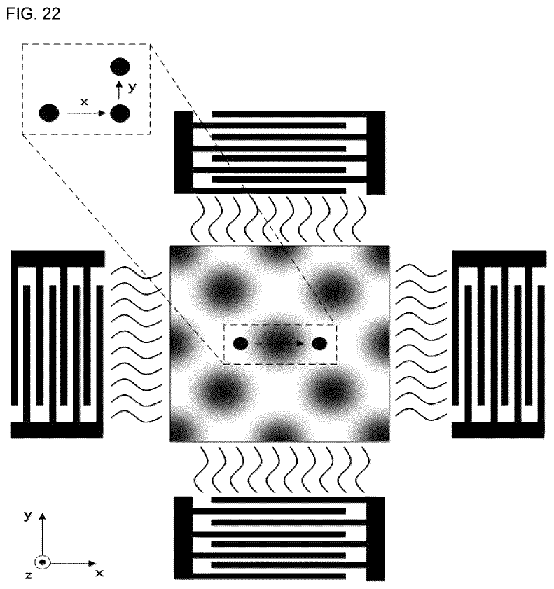

FIG. 22 is a conceptual diagram of a 2D quantum and spin information processing device extended from the 1D surface acoustic wave illustrated in FIG. 21 of the present disclosure. It is possible to achieve spin and quantum information processing using quantum wells by the 2D standing wave generated by 2D arrangement of the plurality of interdigital transducers and the charge confined therein.

1. A substrate for a surface acoustic wave device, comprising:
a 2-dimensional (2D) crystalline hexagonal boron nitride layer,
wherein a surface acoustic wave of the surface acoustic wave device is transmitted through the 2D crystalline hexagonal boron nitride layer.

2. The substrate for the surface acoustic wave device according to claim 1, wherein the 2D crystalline hexagonal boron nitride layer has a phase velocity amounting to 19,600 m/s in an in-plane direction.

3. The substrate for the surface acoustic wave device according to claim 1, wherein an attenuation level of the surface acoustic wave in the 2D crystalline hexagonal boron nitride layer is determined according to an amount of an isotope of boron in the 2D crystalline hexagonal boron nitride layer.

4. The substrate for the surface acoustic wave device according to claim 1, wherein the substrate for the surface acoustic wave device comprises:
the 2D crystalline hexagonal boron nitride layer;
a piezoelectric material layer stacked on the boron nitride layer; and
electrodes stacked on the piezoelectric material layer, and
wherein harmonics are formed from an interfacial structure between the hexagonal boron nitride layer and the piezoelectric material layer.

5. The substrate for the surface acoustic wave device according to claim 4, wherein a velocity of the surface acoustic wave of the surface acoustic wave device has a higher velocity in the 2D crystalline hexagonal boron nitride layer than a velocity in the piezoelectric material layer.

6. A surface acoustic wave device, comprising:
a substrate;
an input transducer stacked on the substrate and configured to induce a surface acoustic wave; and
an output transducer stacked on the substrate and configured to detect the induced surface acoustic wave on the substrate,
wherein the substrate is defined in claim 1.

7. The surface acoustic wave device according to claim 6, wherein the input transducer and the output transducer are interdigital type transducers.

8. The surface acoustic wave device according to claim 7, wherein the input transducer induces the surface acoustic wave by applying a potential difference to cause regular contraction and expansion to the 2D crystalline hexagonal boron nitride layer, and
wherein the output transducer reads the potential difference of the 2D crystalline hexagonal boron nitride layer caused by the surface acoustic wave.

9. The surface acoustic wave device according to claim 7, wherein the input transducer or the output transducer includes Al, Au, Pt, Ni, Cr, Cd, Ti, W, Pd, Ag, Cu, Ru, Rh, Ta, Mo, Nb, doped NiSi, TaSiN, ErSi_{1.7}, PtSi, WSi₂, NbN conductive ceramics, doped Si, Ge, III-V compound semiconductors and a combination thereof.

10. The surface acoustic wave device according to claim 7, wherein the support substrate does not affect insulating properties of the 2D crystalline hexagonal boron nitride layer stacked thereon, and exposes all or part of the stacked 2D crystalline hexagonal boron nitride layer upward or downward of the support substrate.

11. The surface acoustic wave device according to claim 7, wherein the surface acoustic wave device has a center frequency between 26.5 GHz and 40 GHz.

12. The surface acoustic wave device according to claim 8, wherein a pair of interdigital input transducer and interdigital output transducer is included, and each of the pair of input and output transducers is different in dimension.

13-16. (canceled)
